(19) United States
(12) Patent Application Publication
(10) Pub. No.: US 2016/0298467 A1
(43) Pub. Date: Oct. 13, 2016

(54) ARTICLE HAVING VARIABLE COATING

(71) Applicant: UNITED TECHNOLOGIES CORPORATION, Farmington, CT (US)

(72) Inventor: Mark T. Ucasz, Middleton, CT (US)

(21) Appl. No.: 15/036,109

(22) PCT Filed: Nov. 17, 2014
(86) PCT No.: PCT/US2014/065860

§ 371 Date: May 12, 2016

Related U.S. Application Data
(60) Provisional application No. 61/905,475, filed on Nov. 18, 2013.

(51) Int. Cl. F01D 5/28; C23C 4/134; C23C 4/11; C23C 14/08

(52) U.S. Cl. CPC F01D 5/288; C23C 14/083; C23C 4/134; C23C 4/11; F05D 2230/90; F05D 2240/303; F05D 2300/21; F05D 2300/5024; F05D 2300/606; F05D 2300/608; F05D 2300/6111

(57) ABSTRACT

A coated article includes a substrate and a continuous ceramic-based coating supported on the substrate. The ceramic-based coating varies in at least one of composition and microstructure by location on the substrate and with respect to localized property requirements. In one example, the coated article is an article of a gas turbine engine.

### CROSS-REFERENCE TO RELATED APPLICATIONS

This application claims priority to U.S. Provisional Application No. 61/905,475, filed Nov. 18, 2013.

### BACKGROUND

A gas turbine engine typically includes a fan section, a compressor section, a combustor section and a turbine section. Air entering the compressor section is compressed and delivered into the combustion section where it is mixed with fuel and ignited to generate a high-speed exhaust gas flow. The high-speed exhaust gas flow expands through the turbine section to drive the compressor and the fan section. The compressor section typically includes low and high pressure compressors, and the turbine section includes low and high pressure turbines. Airfoils in the engine can be coated with a ceramic thermal barrier coating to protect the airfoils from the high-temperature gas flow.

### SUMMARY

A coated article according to an example of the present disclosure includes a substrate and a continuous ceramic-based coating supported on the substrate. The ceramic-based coating varyies in at least one of composition and microstructure by location on the substrate and with respect to localized property requirements.

In a further embodiment of any of the foregoing embodiments, the localized property requirements are selected from the group consisting of thermal conductivity, spallation resistance, environmental resistance, thermochemical resistance, thermomechanical resistance, oxidation resistance, corrosion resistance, erosion resistance, electromagnetic emissions, impact resistance, fracture toughness, hardness, and combinations thereof.

In a further embodiment of any of the foregoing embodiments, the ceramic-based coating varies in composition.

In a further embodiment of any of the foregoing embodiments, the ceramic-based coating includes a first location L1 that predominantly includes yttria stabilized zirconia and a second location L2 that predominantly includes gadolinia stabilized zirconia.

In a further embodiment of any of the foregoing embodiments, the ceramic-based coating has a functionally graded region between the first location L1 and the second location L2.

In a further embodiment of any of the foregoing embodiments, the ceramic-based coating includes a first location L1 having a functionally graded composition and a second location L2 that has a homogenous composition.

In a further embodiment of any of the foregoing embodiments, the ceramic-based coating includes a first location L1 that is multilayered with distinct layers of differing compositions and a second location L2 that has a homogenous composition.

In a further embodiment of any of the foregoing embodiments, the ceramic-based coating includes a first location L1 that predominantly includes a first composition and a second location L2 that predominantly includes a second, different composition, with respective edges of the first location L1 and the second location L2 partially overlapping.

In a further embodiment of any of the foregoing embodiments, the respective edges of the first location L1 and the second location L2 overlap at a sloped interface.

In a further embodiment of any of the foregoing embodiments, the ceramic-based coating varies in microstructure.

In a further embodiment of any of the foregoing embodiments, the ceramic-based coating includes a first location L1 that has a columnar microstructure and a second location L2 that has non-columnar microstructure.

In a further embodiment of any of the foregoing embodiments, the substrate is an airfoil, and the ceramic-based coating varies between a leading edge of the airfoil and another location on the airfoil to provide better impact resistance and erosion resistance at the leading edge relative to the other location on the airfoil and the other locations are provided with better spallation resistance and environmental resistance relative to the leading edge.

In a further embodiment of any of the foregoing embodiments, the ceramic-based coating varies in composition, and the composition includes zirconate.

In a further embodiment of any of the foregoing embodiments, the ceramic-based coating varies in composition, and the composition includes at least one of alumina-containing ceramic material, mullite, zircon, rare earth silicates, and combinations thereof.

A gas turbine engine according to an example of the present disclosure includes an article having a substrate and a continuous ceramic-based coating supported on the substrate. The ceramic-based coating varyies in at least one of coating architecture, microstructure, and composition by location on the substrate with respect to localized property requirements.

A further embodiment of any of the foregoing embodiments includes a compressor section, a combustor in fluid communication with the compressor section, and a turbine section in fluid communication with the combustor.

In a further embodiment of any of the foregoing embodiments, the localized property requirements are selected from the group consisting of thermal conductivity, spallation resistance, environmental resistance, erosion, and combinations thereof.

In a further embodiment of any of the foregoing embodiments, the ceramic-based coating varies in composition.

In a further embodiment of any of the foregoing embodiments, the ceramic-based coating varies in microstructure.

In a further embodiment of any of the foregoing embodiments, the substrate is an airfoil, and the ceramic-based coating varies between a leading edge of the airfoil and another location on the airfoil to provide better impact resistance and erosion resistance at the leading edge relative to the other location on the airfoil and the other locations are provided with better spallation resistance and environmental resistance relative to the leading edge.

### BRIEF DESCRIPTION OF THE DRAWINGS

The various features and advantages of the present disclosure will become apparent to those skilled in the art from the following detailed description. The drawings that accompany the detailed description can be briefly described as follows.

FIG. 1 illustrates a gas turbine engine.

FIG. 2 illustrates a representative portion of a coated article that can be used in the gas turbine engine of FIG. 1.

FIG. 3 illustrates a representative portion of a multilayered coating structure.

FIG. 4 illustrates a partially overlapping joint of a coating.

FIG. 5A illustrates a columnar microstructure of a portion of a ceramic-based coating.

FIG. 5B illustrates a non-columnar microstructure of a portion of a ceramic-based coating.

FIG. 6 illustrates a coated airfoil that can be used in the gas turbine engine of FIG. 1.

### DETAILED DESCRIPTION

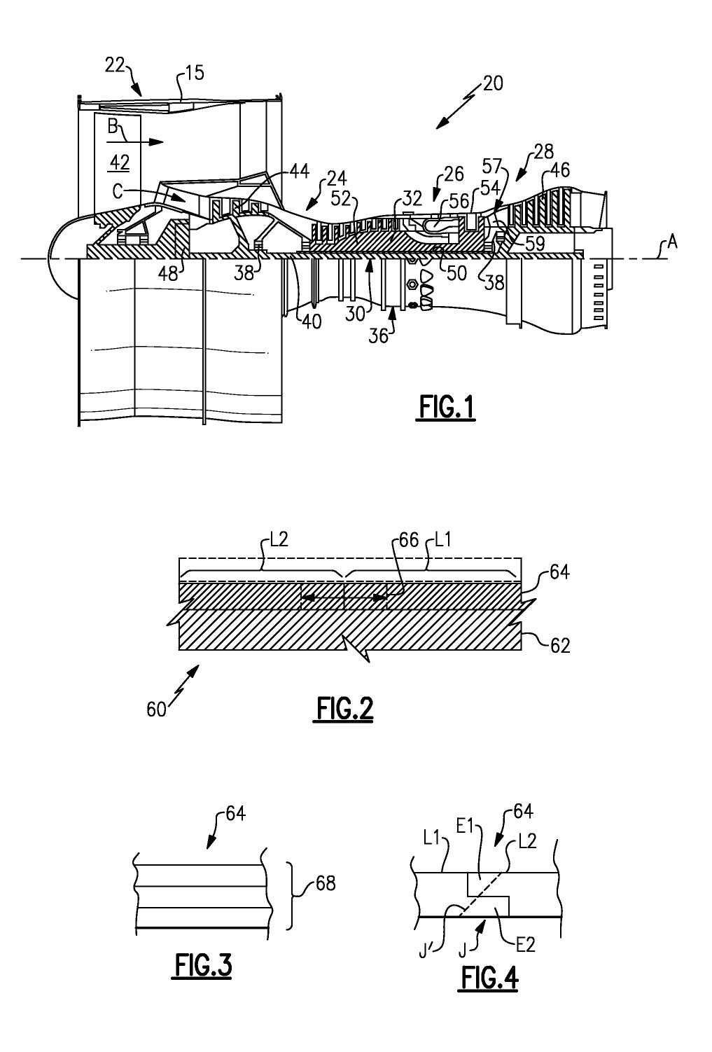

FIG. 1 schematically illustrates a gas turbine engine 20. The gas turbine engine 20 is disclosed herein as a two-spool turbofan that generally incorporates a fan section 22, a compressor section 24, a combustor section 26 and a turbine section 28. Alternative engines might include an augmentor section (not shown) among other systems or features. The fan section 22 drives air along a bypass flow path B in a bypass duct defined within a nacelle 15, while the compressor section 24 drives air along a core flow path C for compression and communication into the combustor section 26 then expansion through the turbine section 28. Although depicted as a two-spool turbofan gas turbine engine in the disclosed non-limiting embodiment, it should be understood that the concepts described herein are not limited to use with two-spool turbofans as the teachings may be applied to other types of turbine engines including three-spool architectures.

The exemplary engine 20 generally includes a low speed spool 30 and a high speed spool 32 mounted for rotation about an engine central longitudinal axis A relative to an engine static structure 36 via several bearing systems 38. It should be understood that various bearing systems 38 at various locations may alternatively or additionally be provided, and the location of bearing systems 38 may be varied as appropriate to the application.

The low speed spool 30 generally includes an inner shaft 40 that interconnects a fan 42, a first (or low) pressure compressor 44 and a first (or low) pressure turbine 46. The inner shaft 40 is connected to the fan 42 through a speed change mechanism, which in exemplary gas turbine engine 20 is illustrated as a geared architecture 48 to drive the fan 42 at a lower speed than the low speed spool 30. The high speed spool 32 includes an outer shaft 50 that interconnects a second (or high) pressure compressor 52 and a second (or high) pressure turbine 54. A combustor 56 is arranged in exemplary gas turbine 20 between the high pressure compressor 52 and the high pressure turbine 54. A mid-turbine frame 57 of the engine static structure 36 is arranged generally between the high pressure turbine 54 and the low pressure turbine 46. The mid-turbine frame 57 further supports bearing systems 38 in the turbine section 28. The inner shaft 40 and the outer shaft 50 are concentric and rotate via bearing systems 38 about the engine central longitudinal axis A which is collinear with their longitudinal axes.

The core airflow is compressed by the low pressure compressor 44 then the high pressure compressor 52, mixed and burned with fuel in the combustor 56, then expanded over the high pressure turbine 54 and low pressure turbine 46. The mid-turbine frame 57 includes airfoils 59 which are in the core airflow path C. The turbines 46, 54 rotationally drive the respective low speed spool 30 and high speed spool 32 in response to the expansion. It will be appreciated that each of the positions of the fan section 22, compressor section 24, combustor section 26, turbine section 28, and fan drive gear system 48 may be varied. For example, gear system 48 may be located aft of combustor section 26 or even aft of turbine section 28, and fan section 22 may be positioned forward or aft of the location of gear system 48.

The engine 20 in one example is a high-bypass geared aircraft engine. In a further example, the engine 20 bypass ratio is greater than about six (6), with an example embodiment being greater than about ten (10), the geared architecture 48 is an epicyclic gear train, such as a planetary gear system or other gear system, with a gear reduction ratio of greater than about 2.3 and the low pressure turbine 46 has a pressure ratio that is greater than about five. In one disclosed embodiment, the engine 20 bypass ratio is greater than about ten (10:1), the fan diameter is significantly larger than that of the low pressure compressor 44, and the low pressure turbine 46 has a pressure ratio that is greater than about five 5:1. Low pressure turbine 46 pressure ratio is pressure measured prior to inlet of low pressure turbine 46 as related to the pressure at the outlet of the low pressure turbine 46 prior to an exhaust nozzle. The geared architecture 48 may be an epicycle gear train, such as a planetary gear system or other gear system, with a gear reduction ratio of greater than about 2.3:1. It should be understood, however, that the above parameters are only exemplary of one embodiment of a geared architecture engine and that the present invention is applicable to other gas turbine engines including direct drive turbofans.

A significant amount of thrust is provided by the bypass flow B due to the high bypass ratio. The fan section 22 of the engine 20 is designed for a particular flight condition—typically cruise at about 0.8 Mach and about 35,000 feet. The flight condition of 0.8 Mach and 35,000 ft, with the engine at its best fuel consumption—also known as “bucket cruise Thrust Specific Fuel Consumption (“TSFC”)”—is the industry standard parameter of lbm of fuel being burned divided by lbf of thrust the engine produces at that minimum point. “Low fan pressure ratio” is the pressure ratio across the fan blade alone, without a Fan Exit Guide Vane (“FEGV”) system. The low fan pressure ratio as disclosed herein according to one non-limiting embodiment is less than about 1.45. “Low corrected fan tip speed” is the actual fan tip speed in ft/sec divided by an industry standard temperature correction of [(Tram ° R)/(518.7 ° R)]0.5. The “Low corrected fan tip speed” as disclosed herein according to one non-limiting embodiment is less than about 1150 ft/second.

FIG. 2 illustrates a representative portion of a coated article 60 that can, in some examples, be used in the gas turbine engine 20. For example, the article 60 can be an airfoil, such as a blade or vane, a blade outer air seal, a rotor disk, combustor panel, augmentor liner or other article that would benefit from the examples disclosed herein. The disclosure is not limited to gas turbine engine articles, and it is to be understood that the disclosure can also be applied in other machines or systems, such as but not limited to internal combustion engines for articles such as turbo chargers, manifolds, exhaust pipes, and waste gates. The article 60 includes a substrate 62 and a continuous ceramic-based coating 64 supported on the substrate 62. The substrate 62 can be a structural body of the article or an intermediate coating that is between the ceramic-based coating 64 and a structural body of the article, for example.

At least one of the chemical composition and the microstructure [MLK1] of the ceramic-based coating 64 vary by location on the substrate 62 with respect to localized property requirements. For example, as shown in FIG. 2, the ceramic-based coating 64 has a first composition, microstructure, or both, at location L1 and a second composition, microstructure, or both, at location L2 lateral of location L1.

The composition, microstructure, or both, of the ceramic-based coating 64 can vary by location to tailor the properties of the ceramic-based coating 64 according to localized property requirements. For example, the article 60 can have different localized requirements for thermal conductivity, spallation resistance, environmental resistance (oxidation, thermochemical, thermomechanical and corrosion resistance), electromagnetic emissions, impact resistance, fracture toughness, erosion resistance, hardness, or combinations thereof. By varying the composition, microstructure, or both, between different locations on the article 60, the localized property requirements can be tailored to the particular locations and thus can enhance the desired properties instead of durability of the article 60.

In one example of a varying composition of the ceramic-based coating 64, the first location L1 predominantly includes yttria stabilized zirconia (YSZ) and the second location L2 predominantly includes gadolinia stabilized zirconia (GSZ). Alternatively, other ceramic compositions or other compositions of zirconia or partially or fully stabilized zirconia can be used. In a further example, the YSZ includes 6-22 wt % yttria and, for instance, can include 7 wt % yttria. The GSZ can include 25-64 wt % gadolinia and, for instance, can include 59 wt % gadolinia. The YSZ can provide higher fracture toughness than GSZ, and GSZ can provide a lower thermal conductivity than YSZ.

In further examples, the composition of the ceramic-based coating 64 at the first location L1 or the second location L2 can include cubic/fluorite/pyrochlore/delta phase fully stabilized zirconates, where stabilizers are any oxide or mix of oxides including lanthanide series elements Y, Sc, Mg, Ca, or further modified with Ta, Nb, Ti, Hf. One example composition is gadolinia stabilized zirconia of having a composition Gd₂Zr₂O₇ and compositions disclosed in U.S. Pat. Nos. 6,117,560 and 6,177,200, compositions incorporated herein by reference.

In further examples, the composition of the ceramic-based coating 64 at the first location L1 or the second location L2 can include alumina-containing ceramic material, mullite, zircon (ZrSiO₄), rare earth silicates, combinations of at least one of the foregoing, and the like. Example rare earth silicates can include, but are not limited to, yttrium silicate, yttrium disilicate, magnesium aluminate spinel, and the like.

In a further example, the ceramic-based coating 64 can have a functionally graded region 66 (laterally graded) between the first location L1 and the second location L2. The functionally graded region 66 is a compositional transition from the composition of the ceramic-based coating in the first location L1 to the composition of the ceramic-based coating 64 in the second location L2. In one example, the composition transitions from YSZ in the first location L1 to GSZ in the second location L2.

In another example, the ceramic-based coating 64 has a functionally graded composition at the first location L1 and a homogenous composition at the second location L2. For instance, the composition in the first location L1 gradually changes as a function of distance from the surface of the substrate 62, while the composition in the second location L2 is constant or substantially constant as a function of distance from the surface of the substrate 62.

In another example, shown in part in FIG. 3, the ceramic-based coating 64 can have a multilayered structure, represented at 68, in the first location L1, with distinct layers of differing compositions, and a homogenous composition in the second location L2. For instance, the first location L1 can include alternating YSZ/GSZ layers, but the layers are not limited to these compositions, and the second location L2 can include a homogenous composition of YSZ or GSZ.

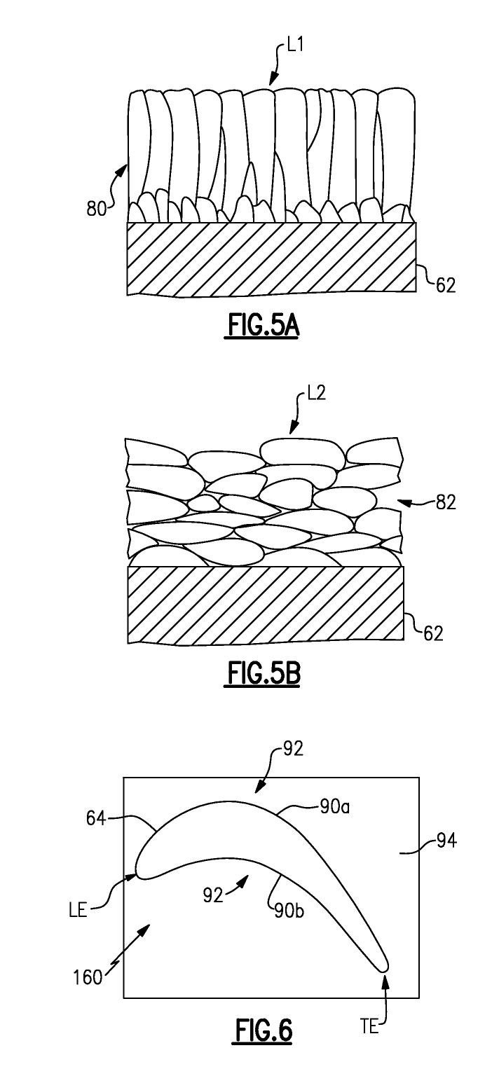

In another example, shown in part in FIG. 4, the ceramic-based coating 64 can have a first composition in the first location L1 and a second, different composition in the second location L2, with respective edges E1 and E2 of the first location and the second location partially overlapping at joint (J). The overlapping joint prevents a gap where the locations L1 and L2 meet. Alternatively, the edges E1 and E2 can overlap at a sloped interface, represented at J′, such as a 45° angle interface.

In a further example shown in FIGS. 5A and 5B, the ceramic-based coating 64 can vary in microstructure and has a columnar microstructure 80 in the first location L1 and a non-columnar microstructure 82 in the second location L2. In the columnar microstructure 80, the grains of the ceramic material are oriented with long axes oriented in a controlled angle relative to the surface of the substrate 62, such as substantially perpendicular to the surface of the substrate 62. In the non-columnar microstructure 82, the grains are not oriented with long axes perpendicular to the surface of the substrate 62. In this example, the grains of the non-columnar microstructure 82 are oriented with long axes parallel to the surface of the substrate 62.

For example, the columnar microstructure 80 and the non-columnar microstructure 82 are representative of the deposition techniques used to deposit those portions of the ceramic-based coating 64. For instance, the columnar microstructure 80 is representative of deposition by electron beam physical vapor deposition (EBPVD), suspension plasma spray (SPS), plasma spray or by other methods and the non-columnar microstructure 82 is representative of plasma spray deposition, such as air plasma spray. The microstructures 80/82 can provide different properties between the first and second locations L1/L2. As an example, for a given ceramic material, the columnar microstructure 80 can provide better fatigue resistance and the non-columnar microstructure 82 can provide better thermal resistance. Other non-limiting examples of differences in microstructures can include differences in physical characteristics, porosity, crystallographic orientation, deposition splat size, column geometry, and combinations thereof.

FIG. 6 illustrates another example coated article 160. In this example, the coated article 160 is an airfoil that can be used in the gas turbine engine 20. For example, the airfoil 160 can be a turbine airfoil in the turbine section 28 of the engine 20, but is not limited to turbine airfoils. In this example, the airfoil 160 includes the ceramic-based coating 64 continuously supported on the outer surface thereof. The airfoil 160 has a leading edge LE and a trailing edge TE that are joined by opposed first and second sides 90a/90b. The leading edge of the airfoil 160 can be susceptible to high temperatures and impact from foreign objects in the gas stream that flows across the surfaces of the airfoil 160. Thus, the ceramic-based coating 64 varies in composition, microstructure, or both, between the leading edge of the airfoil 160 and the other locations of the airfoil 160, represented at 92, to provide better impact resistance and erosion resistance at the leading edge relative to the other locations 92 on the airfoil 160. For example, the leading edge (location L1) and platform 94 can have a homogeneous YSZ composition for better impact and erosion resistance and the other areas 92 (location L2) can have a functionally graded YSZ/GSZ composition for better thermal protection.

Although a combination of features is shown in the illustrated examples, not all of them need to be combined to realize the benefits of various embodiments of this disclosure. In other words, a system designed according to an embodiment of this disclosure will not necessarily include all of the features shown in any one of the Figures or all of the portions schematically shown in the Figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from the essence of this disclosure. The scope of legal protection given to this disclosure can only be determined by studying the following claims.

What is claimed is:

1. A coated article comprising:
a substrate; and
a continuous ceramic-based coating supported on the substrate, the ceramic-based coating varying in at least one of:
composition and
microstructure
by location on the substrate and with respect to localized property requirements.

2. The coated article as recited in claim 1, wherein the localized property requirements are selected from the group consisting of thermal conductivity, spallation resistance, environmental resistance, thermochemical resistance, thermomechanical resistance, oxidation resistance, corrosion resistance, erosion resistance, electromagnetic emissions, impact resistance, fracture toughness, hardness, and combinations thereof.

3. The coated article as recited in claim 1, wherein the ceramic-based coating varies in composition.

4. The coated article as recited in claim 3, wherein the ceramic-based coating includes a first location L1 that predominantly includes yttria stabilized zirconia and a second location L2 that predominantly includes gadolinia stabilized zirconia.

5. The coated article as recited in claim 4, wherein the ceramic-based coating has a functionally graded region between the first location L1 and the second location L2.

6. The coated article as recited in claim 3, wherein the ceramic-based coating includes a first location L1 having a functionally graded composition and a second location L2 that has a homogenous composition.

7. The coated article as recited in claim 3, wherein the ceramic-based coating includes a first location L1 that is multilayered with distinct layers of differing compositions and a second location L2 that has a homogenous composition.

8. The coated article as recited in claim 3, wherein the ceramic-based coating includes a first location L1 that predominantly includes a first composition and a second location L2 that predominantly includes a second, different composition, with respective edges of the first location L1 and the second location L2 partially overlapping.

9. The coated article as recited in claim 8, wherein the respective edges of the first location L1 and the second location L2 overlap at a sloped interface.

10. The coated article as recited in claim 1, wherein the ceramic-based coating varies in microstructure.

11. The coated article as recited in claim 10, wherein the ceramic-based coating includes a first location L1 that has a columnar microstructure and a second location L2 that has non-columnar microstructure.

12. The coated article as recited in claim 1, wherein the substrate is an airfoil, and the ceramic-based coating varies between a leading edge of the airfoil and another location on the airfoil to provide better impact resistance and erosion resistance at the leading edge relative to the other location on the airfoil and the other locations are provided with better spallation resistance and environmental resistance relative to the leading edge.

13. The coated article as recited in claim 1, wherein the ceramic-based coating varies in composition, and the composition includes zirconate.

14. The coated article as recited in claim 1, wherein the ceramic-based coating varies in composition, and the composition includes at least one of alumina-containing ceramic material, mullite, zircon, rare earth silicates, and combinations thereof.

15. A gas turbine engine comprising:
an article having a substrate and a continuous ceramic-based coating supported on the substrate, the ceramic-based coating varying in at least one of:
coating architecture,
microstructure, and
composition
by location on the substrate with respect to localized property requirements.

16. The gas turbine engine as recited in claim 15, including a compressor section, a combustor in fluid communication with the compressor section, and a turbine section in fluid communication with the combustor.

17. The gas turbine engine as recited in claim 15, wherein the localized property requirements are selected from the group consisting of thermal conductivity, spallation resistance, environmental resistance, erosion, and combinations thereof.

18. The gas turbine engine as recited in claim 15, wherein the ceramic-based coating varies in composition.

19. The gas turbine engine as recited in claim 15, wherein the ceramic-based coating varies in microstructure.

20. The gas turbine engine as recited in claim 15, wherein the substrate is an airfoil, and the ceramic-based coating varies between a leading edge of the airfoil and another location on the airfoil to provide better impact resistance and erosion resistance at the leading edge relative to the other location on the airfoil and the other locations are provided with better spallation resistance and environmental resistance relative to the leading edge.
